(19) United States
(12) Patent Application Publication
(10) Pub. No.: US 2025/0368860 A1
(43) Pub. Date: Dec. 4, 2025

(54) POLISHING AGENT, POLISHING METHOD, METHOD FOR MANUFACTURING SEMICONDUCTOR COMPONENT, AND ADDITIVE SOLUTION FOR POLISHING AGENT

(71) Applicant: AGC Inc., Tokyo (JP)

(72) Inventors: Masatoshi AKAJI, Tokyo (JP); Yasuhisa NOZAWA, Tokyo (JP); Atsuyoshi TAKENAKA, Tokyo (JP)

(73) Assignee: AGC Inc., Tokyo (JP)

(21) Appl. No.: 19/248,987

(22) Filed: Jun. 25, 2025

Related U.S. Application Data
(63) Continuation of application No. PCT/JP2023/042574, filed on Nov. 28, 2023.

(30) Foreign Application Priority Data
Dec. 27, 2022 (JP) 2022-209603

(51) Int. Cl. C09G 1/02; B24B 37/04; C09K 3/14; H01L 21/3105

(52) U.S. Cl. CPC C09G 1/02; B24B 37/044; C09K 3/1409; H01L 21/31053

(57) ABSTRACT

An object of the present invention is to provide a polishing agent capable of obtaining a high selection ratio between a silicon oxide film and a stopper film while maintaining a polishing speed of the silicon oxide film, a polishing agent additive liquid for preparing the polishing agent, a polishing method capable of performing high-speed polishing, and a method for manufacturing a semiconductor component using the polishing method. The polishing agent contains abrasive grains, a water-soluble polymer, and water. The water-soluble polymer is a block copolymer containing a hydrophobic monomer and an anionic monomer. The content of the hydrophobic monomer in the water-soluble polymer is 50 mol % or more.

### INCORPORATION BY REFERENCE

This application is based upon and claims the benefit of priority from Japanese Patent Application 2022-209603 filed on Dec. 27, 2022, and PCT application No. PCT/JP2023/042574 filed on Nov. 28, 2023, the disclosure of which is incorporated herein in its entirety by reference.

### BACKGROUND

The present invention relates to a polishing agent, a polishing method, a method for manufacturing a semiconductor component, and an additive solution for a polishing agent.

In recent years, with an increase in integration and functionality of a semiconductor integrated circuit, development of a microfabrication technique for miniaturization and densification of a semiconductor element has been advanced. Conventionally, in manufacture of a semiconductor integrated circuit device (hereinafter, also referred to as a semiconductor device), in order to prevent a problem that unevenness (step) on a layer surface exceeds a focal depth of lithography and sufficient resolution cannot be obtained, an interlayer insulating film, embedded wiring, and the like are planarized using a chemical mechanical planarization method (chemical mechanical polishing: hereinafter referred to as CMP). As a demand for high definition and miniaturization of an element is stricter, an importance of high planarization by CMP is increasing more and more.

In recent years, in manufacture of a semiconductor device, in order to further miniaturize a semiconductor element, a separation method using a shallow trench having a small element separation width (shallow trench isolation: hereinafter referred to as STI) has been introduced.

STI is a method for forming an electrically insulated element region by forming a trench (groove) in a silicon substrate and embedding an insulating film in the trench. An example of STI will be described with reference to FIGS. 1A and 1B. In this example, first, as illustrated in FIG. 1A, an element region of a silicon substrate 1 is masked with a silicon nitride film 2 or the like, then a trench 3 is formed in the silicon substrate 1, and an insulating film such as a silicon oxide film 4 is deposited so as to fill the trench 3. Subsequently, by polishing and removing the silicon oxide film 4 on the silicon nitride film 2 as a protrusion by CMP while leaving the silicon oxide film 4 in the trench 3 as a recess, an element isolation structure in which the silicon oxide film 4 is embedded in the trench 3 is obtained as illustrated in FIG. 1B. Although not illustrated, the silicon nitride film 2 may also be removed.

In CMP in STI, by increasing a selection ratio (polishing speed ratio) between a silicon dioxide film and a stopper film, a progress of polishing can be stopped when the stopper film is exposed. Examples of such a stopper film include a nitride film and polysilicon. In the polishing method using the stopper film, a smoother surface can be obtained as compared with a surface obtained by a normal polishing method. A recent CMP technique requires that the selection ratio is high.

For example, Japanese Unexamined Patent Application Publication No. 2019-87660 discloses a polishing agent containing a specific water-soluble polymer, cerium oxide particles, and water and having a pH of 4 to 9 as a method for increasing a selection ratio between a silicon dioxide film and a silicon nitride film.

### SUMMARY

In view of the above problems, an object of the present disclosure is to provide a polishing agent capable of obtaining a high selection ratio between a silicon oxide film and a stopper film while maintaining a polishing speed of the silicon oxide film, an additive solution for a polishing agent a polishing agent additive liquid for preparing the polishing agent, a polishing method capable of performing high-speed polishing, and a method for manufacturing a semiconductor component using the polishing method.

The present disclosure provides a polishing agent, a polishing method, a method for manufacturing a semiconductor component, and an additive solution for a polishing agent having the following configurations [1] to [15].
[1] A polishing agent containing abrasive grains, a water-soluble polymer, and water, in which
   the water-soluble polymer is a block copolymer containing a hydrophobic monomer and an anionic monomer, and
   a content of the hydrophobic monomer in the water-soluble polymer is 50 mol % or more.
[2] The polishing agent according to [1], in which the abrasive grains contain at least one selected from the group consisting of silica particles, alumina particles, zirconia particles, cerium compound particles, titania particles, germania particles, and composite particles thereof.
[3] The polishing agent according to [1] or [2], in which the abrasive grains contain ceria particles.
[4] The polishing agent according to any one of [1] to [3], in which a content of the abrasive grains is 0.01 mass % to 10.0 mass % with respect to a total mass of the polishing agent.
[5] The polishing agent according to any one of [1] to [4], in which the hydrophobic monomer contains a compound represented by the following formula (1):

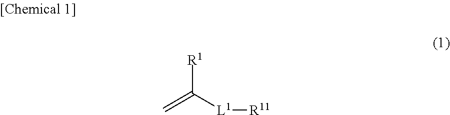

in which
R¹ is a hydrogen atom or a methyl group,
R¹¹ is a hydrocarbon group which may have O or Si between carbon-carbon atoms and in which a hydrogen atom may be replaced with a halogen atom, and
L¹ is a single bond or a divalent linking group.
[6] The polishing agent according to [5], in which the R¹¹ is a hydrocarbon group.
[7] The polishing agent according to any one of [1] to [6], in which the anionic monomer contains a compound represented by the following formula (2):

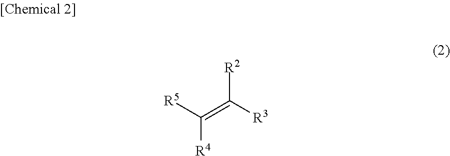

in which
R², R³, R⁴, and R⁵ are each independently a hydrogen atom, a hydrocarbon group, or a group having an anionic group or a salt thereof, at least one of R² to R⁵ is a group having an anionic group or a salt thereof, and when the compound has two or more carboxy groups in a molecule thereof, the carboxy groups may form an anhydride.
[8] The polishing agent according to [7], in which the anionic group contains a carboxy group, a sulfo group, a phosphonic acid, a phosphate, or a phenolic hydroxy group.
[9] The polishing agent according to [7] or [8], in which the anionic group contains a carboxy group.
[10] The polishing agent according to any one of [1] to [9], in which the water-soluble polymer has a weight average molecular weight of 2,000 to 50,000.
[11] The polishing agent according to any one of [1] to [10], in which a content of the water-soluble polymer is 0.02 mass % to 0.5 mass % with respect to a total mass of the polishing agent.
[12] The polishing agent according to any one of [1] to [11], having a pH of 4 to 13.
[13] A polishing method for bringing a polishing surface of a semiconductor substrate and a polishing pad into contact with each other while supplying a polishing agent, and performing polishing by relative movement between the polishing surface and the polishing pad,
   in which the polishing agent is the polishing agent according to any one of [1] to [12].
[14] A method for manufacturing a semiconductor component, the method including segmenting a semiconductor substrate having a polishing surface polished by the polishing method according to to obtain a semiconductor component.
[15] An additive solution for a polishing agent containing a water-soluble polymer and water, in which
   the water-soluble polymer is a block copolymer containing a hydrophobic monomer and an anionic monomer, and
   a content of the hydrophobic monomer in the water-soluble polymer is 50 mol % or more.

According to the present disclosure, it is possible to provide a polishing agent capable of obtaining a high selection ratio between a silicon oxide film and a stopper film while maintaining a polishing speed of the silicon oxide film, an additive solution for a polishing agent for preparing the polishing agent, a polishing method capable of performing high-speed polishing, and a method for manufacturing a semiconductor component using the polishing method.

The above and other objects, features and advantages of the present disclosure will become more fully understood from the detailed description given hereinbelow and the accompanying drawings.

### BRIEF DESCRIPTION OF DRAWINGS

FIG. 1A is a view illustrating an example of a polishing method, and is a cross-sectional view illustrating a state of a polishing target before polishing;

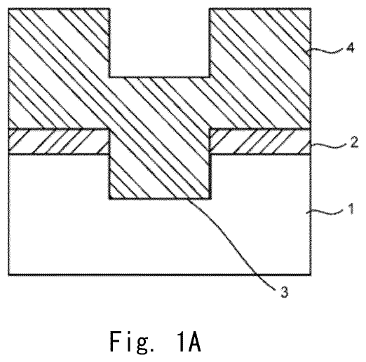

FIG. 1B is a view illustrating an example of a polishing method, and is a cross-sectional view illustrating a state of a polishing target after polishing; and

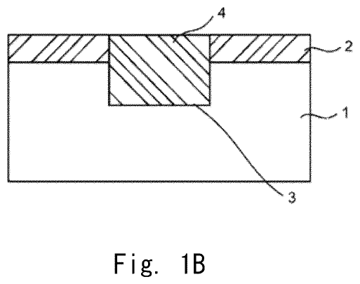

FIG. 2 is a schematic view illustrating an example of a polishing device.

### DESCRIPTION OF EMBODIMENTS

Hereinafter, an embodiment of the present invention will be described. The present invention is not limited to the following embodiment, and other embodiments may also fall within the scope of the present invention as long as they are consistent with the gist of the present invention. For clarity of description, the following description and drawings are simplified as appropriate. In addition, for description, each member in the drawings may be largely different in scale.

Note that, in the present invention, “polishing surface” is a polishing target surface to be polished, and means, for example, a surface. In the present specification, a surface in an intermediate stage appearing in a semiconductor substrate in a process of manufacturing a semiconductor device is also included in the “polishing surface”.

“Silicon oxide” is mainly silicon dioxide, but is not limited thereto, and may contain a silicon oxide other than silicon dioxide.

“Selection ratio” means a ratio (RA/RB) of a polishing speed (RA) of a polishing target A (for example, a silicon oxide film) to a polishing speed (RB) of a stopper film B (for example, a silicon nitride film).

In the present invention, the water-soluble polymer means “a polymer that dissolves in an amount of 10 mg or more in 100 g of water at 25° C.”.

“(Meth)acryl” is a generic term for “methacryl” and “acryl”, and (meth)acryloyl, (meth)acrylate, and the like follow this.

In addition, “to” indicating a numerical range includes numerical values described before and after “to” as a lower limit value and an upper limit value unless otherwise specified.

### [Polishing Agent]

The polishing agent according to the present invention (hereinafter, also referred to as the present polishing agent) contains abrasive grains, a water-soluble polymer, and water. The water-soluble polymer is a block copolymer containing a hydrophobic monomer and an anionic monomer. The content of the hydrophobic monomer in the water-soluble polymer is 50 mol % or more.

When the present polishing agent is used, for example, for CMP of a polishing surface including a silicon oxide film (for example, a silicon dioxide film) in STI, a high polishing speed can be achieved for the silicon oxide film while suppressing polishing scratches. On the other hand, polishing of a stopper film is suppressed, a high selection ratio between the silicon oxide film and the stopper film can be obtained, and polishing with high flatness can be implemented.

A mechanism by which the present polishing agent exerts the above effect is not clear in some aspects, but is estimated as follows. It is considered that an anionic group is easily adsorbed on the stopper film on the polishing surface. In the present embodiment, the polymer is a block copolymer, and has a block of an anionic monomer (hereinafter, also referred to as an anionic block) and a hydrophobic block (hereinafter, also referred to as a hydrophobic block).

The anionic block of the polymer is strongly adsorbed on the stopper film and acts as a protective film of the stopper film during polishing. On the other hand, it is presumed that the hydrophobic block is not adsorbed on the polishing surface and forms an assembly by hydrophobic interaction with a hydrophobic block of another polymer in water as a solvent. As a result, a higher-order structure formed by hydrophobic blocks of a plurality of polymers is formed on the stopper film, and protection performance of the stopper film is improved. As a result, as compared with a random copolymer using a similar monomer, the polishing speed of the stopper film can be significantly reduced, and a polishing agent having a high selection ratio between the silicon oxide film and the stopper film can be obtained.

Note that examples of the stopper film include a compound containing one or more selected from silicon, carbon, hafnium, zirconium, cobalt, ruthenium, molybdenum, titanium, tantalum, and copper, and a nitride or an oxide containing one or more of these. More specifically, examples of the stopper film include: a metal simple substance such as copper, cobalt, ruthenium, molybdenum, titanium, or tantalum; a nitride such as titanium nitride, tantalum nitride, or silicon nitride; an oxide such as zirconia or hafnium oxide; polysilicon, amorphous silicon, hafnium silicate, zirconium silicate, and silicon carbide. Among these, silicon nitride or polysilicon is preferable from a viewpoint of obtaining a higher selection ratio.

The present polishing agent contains at least abrasive grains, a water-soluble polymer, and water, and may further contain other components as long as the effect of the present invention is exhibited. Hereinafter, each component that can be contained in the present polishing agent will be described.

### <Abrasive Grains>

In the present polishing agent, the abrasive grains can be appropriately selected and used from those used as abrasive grains for CMP. Examples of the abrasive grains include at least one selected from the group consisting of silica particles, alumina particles, zirconia particles, cerium compound particles (for example, ceria particles and cerium hydroxide particles), titania particles, germania particles, and core-shell type particles having these particles as core particles. Examples of the silica particles include colloidal silica and fumed silica. As the alumina particles, colloidal alumina can also be used.

The core-shell type particle includes a core particle (for example, a silica particle, an alumina particle, a zirconia particle, a cerium compound particle, a titania particle, or a germania particle) and a thin film covering a surface of the core particle.

Examples of a material of the thin film include at least one selected from oxides such as silica, alumina, zirconia, ceria, titania, germania, iron oxide, manganese oxide, zinc oxide, yttrium oxide, calcium oxide, magnesium oxide, lanthanum oxide, and strontium oxide. In addition, the thin film may be formed of a plurality of nanoparticles formed of these oxides.

A particle size of the core particle is preferably 0.01 μm to 0.5 μm, and more preferably 0.03 um to 0.3 um.

A particle size of the nanoparticle only needs to be smaller than the particle size of the core particle, and is preferably 1 nm to 100 nm, and more preferably 5 nm to 80 nm.

As the abrasive grains, among the particles described above, silica particles, alumina particles, or cerium compound particles are preferable, and cerium compound particles are more preferable from a viewpoint of an excellent polishing speed of an insulating film, and ceria particles are still more preferable from a viewpoint of obtaining a high polishing speed when the polishing surface includes an insulating film (particularly, a silicon oxide film). In the case of the core-shell type particles, the thin film preferably contains silica, alumina, or a cerium compound, and more preferably contains ceria. The abrasive grains can be used singly or in combination of two or more types thereof.

The content of ceria with respect to the total mass of the abrasive grains is preferably 70% mass or more, more preferably 80 mass % or more, still more preferably 90 mass % or more, particularly preferably 95 mass % or more, and most preferably 100 mass %. When the content of ceria with respect to the total mass of the abrasive grains is 70 mass % or more, the polishing speed of the insulating film is particularly easily improved.

The ceria particles can be appropriately selected and used from known ceria particles, and examples thereof include ceria particles manufactured by methods described in Japanese Unexamined Patent Application Publication No. H11-12561, Japanese Unexamined Patent Application Publication No. 2001-35818, and Published Japanese Translation of PCT International Publication for Patent Application, No. 2010-505735. Specifically, examples thereof include: ceria particles obtained by adding an alkali to an aqueous solution of cerium (IV) nitrate ammonium to prepare a cerium hydroxide gel, filtering, washing, and firing the cerium hydroxide gel; ceria particles obtained by pulverizing high-purity cerium carbonate, then firing the pulverized cerium carbonate, and further pulverizing and classifying the fired cerium carbonate; and ceria particles obtained by chemically oxidizing a cerium (III) salt in a liquid.

The ceria particles may contain impurities other than ceria, but the content of ceria in one ceria particle is preferably 80 mass % or more, more preferably 90 mass % or more, still more preferably 95% or more, and most preferably 100 mass % (not containing impurities). When the content of ceria in the ceria particle is 80 mass % or more, the polishing speed of the insulating film is easily improved.

An average particle size of the abrasive grains is preferably 0.01 μm to 0.5 um, and more preferably 0.03 um to 0.3 um. When the average particle size is 0.5 μm or less, mechanical action applied to the polishing surface is small, and therefore occurrence of polishing scratches such as scratches on the polishing surface is suppressed. In addition, when the average particle size is 0.01 um or more, aggregation of the abrasive grains is suppressed, storage stability of the polishing agent is excellent, and the polishing speed is also excellent.

Note that since the abrasive grains are present as aggregated particles (secondary particles) in which primary particles are aggregated in a liquid, the average particle size is an average secondary particle size. The average secondary particle size is measured using a particle size distribution meter such as a laser diffraction/scattering type using a dispersion dispersed in a dispersion medium such as pure water.

The content of the abrasive grains is preferably 0.01 mass % to 10.0 mass %, more preferably 0.05 mass % to 2.0 mass %, still more preferably 0.1 mass % to 1.5 mass %, and particularly preferably 0.15 mass % to 1.0 mass % with respect to the total mass of the polishing agent. When the content ratio of the abrasive grains is the above lower limit value or more, an excellent polishing speed with respect to the polishing surface can be obtained. On the other hand, when the content ratio of the abrasive grains is the above upper limit value or less, aggregation of the abrasive grains can be suppressed, an increase in viscosity of the present polishing agent is suppressed, and handleability is excellent.

### <Water-Soluble Polymer>

In the present polishing agent, the water-soluble polymer is a block copolymer containing a hydrophobic monomer and an anionic monomer, and the content of the hydrophobic monomer in the water-soluble polymer is 50 mol % or more. By using the specific water-soluble polymer, polishing of the stopper film is suppressed, and a high selection ratio between the silicon oxide film and the stopper film can be obtained.

The water-soluble polymer contains at least a hydrophobic block containing a structural unit derived from a hydrophobic monomer and an anionic block containing a structural unit derived from an anionic monomer, and may further contain another structural unit as long as the effect of the present invention is exhibited.

### (Hydrophobic Monomer)

In the present embodiment, the hydrophobic monomer refers to a monomer having a dissolution amount in 100 g of water at 20° C. (hereinafter, also referred to as “solubility”) of 10 g or less. The water-soluble polymer has a hydrophobic block derived from the hydrophobic monomer, whereby polishing of the stopper film is further suppressed. The solubility is preferably 7 g or less, more preferably 5 g or less, still more preferably 3 g or less, and particularly preferably 2 g or less from a viewpoint of hydrophobic interaction between the water-soluble polymers. An octanol/water partition coefficient (log Pow) of the hydrophobic monomer is preferably 0.5 or more, more preferably 0.7 or more, still more preferably 1 or more, and particularly preferably 1.2 or more.

A partition coefficient (log D) of the hydrophobic monomer is preferably 0.5 or more, more preferably 0.7 or more, still more preferably 0.9 or more, further still more preferably 1 or more, and particularly preferably 1.2 or more at a pH of 5.5 to 7.4.

A solubility parameter (SP value) of the hydrophobic monomer is preferably 10.5 or less, more preferably 10.2 or less, still more preferably 10.0 or less, further still more preferably 9.8 or less, and particularly preferably 9.6 or less.

As the hydrophobic monomer, a monomer having no ionic group or hydrophilic group is preferable, and a compound represented by the following formula (1) is more preferable.

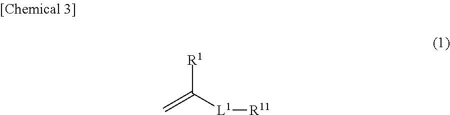

in which
R¹ is a hydrogen atom or a methyl group,
R¹¹ is a hydrocarbon group which may have O or Si between carbon-carbon atoms and in which a hydrogen atom may be replaced with a halogen atom, and
L¹ is a single bond or a divalent linking group.

In the formula (1), R¹¹ is a substituent exhibiting hydrophobicity, and is a hydrocarbon group which may have O or Si between carbon-carbon atoms and in which a hydrogen atom may be replaced with a halogen atom. Examples of the hydrocarbon group in R¹¹ include an alkyl group, an aryl group, and an aralkyl group.

The alkyl group may be linear, branched, or cyclic. The number of carbon atoms in the alkyl group is preferably 1 to 18, and more preferably 1 to 12. Specific examples of the alkyl group include a methyl group, an ethyl group, a n-propyl group, an isopropyl group, a n-butyl group, an isobutyl group, a sec-butyl group, a tert-butyl group, various pentyl groups, various hexyl groups, various octyl groups, various decyl groups, a cyclopentyl group, a cyclohexyl group, a cyclooctyl group, a cyclododecyl group, a bornyl group, and an adamantyl group.

Examples of the aryl group include a phenyl group, a biphenyl group, a naphthyl group, a tolyl group, and a xylyl group. The number of carbon atoms in the aryl group is preferably 6 to 24, and more preferably 6 to 12.

Examples of the aralkyl group include a benzyl group, a phenethyl group, a naphthylmethyl group, and a biphenylmethyl group. The number of carbon atoms in the aralkyl group is preferably 7 to 20, and more preferably 7 to 14.

When R¹¹ has an aromatic ring, a hydrogen atom of the aromatic ring may have a substituent such as a linear or branched alkyl group having 1 to 4 carbon atoms.

The hydrocarbon group in R¹¹ may further have O or Si between carbon-carbon atoms, and in the hydrocarbon group, a hydrogen atom may be replaced with a halogen atom.

Examples of the hydrocarbon group having O or Si between carbon-carbon atoms include an alkylene oxide such as —(CH₂CH₂O)ₓ—CH₂CH₃ or —(CH₂O)ₓ—CH₃, and —CH₂Si(R¹²)₂—CH₃. Here, x represents the number of repeating units, and is preferably an integer of 1 to 18. The two R¹²s are each independently a hydrogen atom or a methyl group.

In addition, in R¹¹, a hydrogen atom of the hydrocarbon group having the above structure may be replaced with a halogen atom. Examples of the halogen atom include F, Cl, Br, and I.

R¹¹ is preferably a hydrocarbon group not containing O, Si, or a halogen atom from a viewpoint of hydrophobicity and easy availability.

L¹ is a single bond or a divalent linking group connecting an unsaturated double bond and R¹¹. Examples of L¹ include an alkylene group having 1 to 8 carbon atoms, —(CH₂CH₂O)ₓ—, —(CH₂O)ₓ—, —CONH—, —COO—, and —C(═O)—. Examples of the alkylene group having 1 to 8 carbon atoms include a methylene group, an ethylene group, a propylene group, a butylene group, a pentylene group, and a hexylene group.

L¹ is preferably a single bond, —CONH—, or ≤COO— from a viewpoint of easy availability.

The hydrophobic monomer can be used singly or in combination of two or more types thereof. The hydrophobic monomer is preferably a combination of a monomer having a ring structure and a monomer having no ring structure from a viewpoint of dispersibility in a polishing agent and the like.

Specific examples of the hydrophobic monomer include: a (meth)acrylate derivative such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, n-pentyl (meth)acrylate, isopentyl (meth)acrylate, n-hexyl (meth)acrylate, 2-ethylhexyl (meth)acrylate, isooctyl (meth)acrylate, n-dodecyl (meth)acrylate, stearyl (meth)acrylate, 1-methylcyclopentyl acrylate, cyclohexyl (meth)acrylate, or benzyl (meth)acrylate;
a (meth)acrylamide derivative such as (meth)acrylamide, N,N-dimethyl (meth)acrylamide, N,N-diethyl (meth)acrylamide, N,N-dibutyl (meth)acrylamide, N-tert-butylacrylamide, N-phenyl (meth)acrylamide, or N-benzyl (meth)acrylamide; and
a vinyl-based monomer such as styrene, methylstyrene, vinyltoluene, p-t-butylstyrene, chloromethylstyrene, vinyl chloride, vinylidene chloride, vinyl fluoride, or vinylidene fluoride.

These monomers can be used singly or in combination of two or more types thereof.

### (Anionic Monomer)

The anionic monomer is a monomer having an anionic group. By having an anionic block derived from an anionic monomer, the water-soluble polymer is strongly adsorbed on the stopper film and acts as a protective film of the stopper film. Examples of the anionic monomer include a compound having an unsaturated bond and an anionic group. Examples of the anionic group include a carboxy group (—COOH), a sulfo group (—SO₃H), a phosphonic acid (—P(—OH)(—OR)(═O)), a phosphate (—OP(—OH)(—OR)(═O)), a phenolic hydroxy group, and salts thereof. Provided that R is a hydrogen atom or an alkyl group. Hereinafter, an anionic group and a salt thereof may be collectively referred to as “anionic groups or the like”.

The anionic monomer preferably contains a compound represented by the following formula (2) from a viewpoint of interaction with the stopper film.

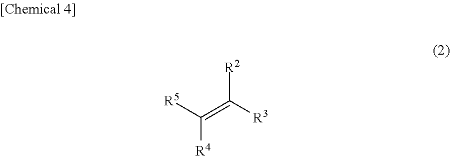

in which
R², R³, R⁴, and R⁵ are each independently a hydrogen atom, a hydrocarbon group, or a group having an anionic group or a salt thereof, at least one of R² to R⁵ is a group having an anionic group or a salt thereof, and when the compound has two or more carboxy groups in a molecule thereof, the carboxy groups may form an anhydride.

Examples of the hydrocarbon group in R² to R⁵ include an alkyl group, an aryl group, and an aralkyl group. Specific examples of the alkyl group, the aryl group, and the aralkyl group include those similar to the specific examples of the R¹¹. In the present polishing agent, the hydrocarbon group in R² to R⁵ is preferably an alkyl group having 1 to 6 carbon atoms from a viewpoint of interaction between the anionic group and the stopper film, and in particular, is preferably a methyl group or an ethyl group, and more preferably a methyl group.

The group having an anionic group or the like in R² to R⁵ preferably has a structure of -L²-R²¹

L² is a single bond or a divalent linking group connecting an unsaturated double bond and R²¹. Examples of L² include an alkylene group having 1 to 8 carbon atoms, a phenylene group, —(CH₂CH₂O)ₓ—R²²—, —(CH₂O)ₓ—R²²—, —CONH—R²²—, and —COO—R²²—. Provided that x is an integer of 1 to 18, and R²² is preferably a single bond or an alkylene group having 1 to 8 carbon atoms.

Examples of the alkylene group in L² and R²² include a methylene group, an ethylene group, a propylene group, a butylene group, a pentylene group, and a hexylene group, and may have a halogen atom as a substituent.

L² is preferably a single bond, —CONH—R²²—, or —COO—R²²— from a viewpoint of easy availability of monomers and the like.

R²¹ is a carboxy group, a sulfo group, a phosphate, a phosphonic acid, a hydroxyphenyl group, or a salt thereof.

When the anionic group is a salt, examples of a counter cation thereof include an alkali metal ion, an alkaline earth metal ion, and an ammonium ion.

In particular, the anionic group in R²¹ is preferably a carboxy group, a sulfo group, or a salt thereof, and more preferably a carboxy group or a salt thereof from a viewpoint of stability of the polymer and protection of the stopper film.

The number of anionic groups in one molecule of the anionic monomer only needs to be 1 or more, and is preferably 1 or 2 from a viewpoint of polymerizability of the polymer. When the anionic monomer has two carboxy groups in a molecule thereof, the carboxy groups may form an anhydride.

Examples of a suitable combination of R² to R⁵ in formula (2) include: (I) a combination in which R² is a group having an anionic group or the like, and R³ to R⁵ are each independently a hydrogen atom or a hydrocarbon group; (II) a combination in which R² and R³ are each a group having an anionic group or the like, and R⁴ and R⁵ are each independently a hydrogen atom or a hydrocarbon group; and (III) a combination in which R² and R⁵ are each independently a group having an anionic group or the like, and R³ and R⁴ are each independently a hydrogen atom or a hydrocarbon group. In (I) to (III), the hydrocarbon group is preferably a methyl group. In (II) and (III), the anionic group is preferably a carboxy group.

Specific examples of the anionic monomer include (meth)acrylic acid, vinylbenzoic acid, 2-carboxyethyl (meth)acrylate, allylsulfonic acid, methallylsulfonic acid, 2-(meth)acryloyloxyethyl acid phosphate, maleic acid (maleic anhydride), fumaric acid, itaconic acid, citraconic acid, and mesaconic acid. Among these monomers, (meth)acrylic acid, maleic acid, itaconic acid, or fumaric acid is preferable, and (meth)acrylic acid or maleic acid is more preferable from a viewpoint of polymerizability.

The anionic monomer can be used singly or in combination of two or more types thereof.

In the water-soluble polymer, the content of the hydrophobic monomer is 50 mol % or more, preferably 55 mol % or more, and more preferably 60 mol % or more with respect to the total amount of all the monomers. By setting the content of the hydrophobic monomer to 50 mol % or more, polishing of the stopper film can be further suppressed. In addition, in the water-soluble polymer, the content of the hydrophobic monomer is 98 mol % or less, more preferably 96 mol % or less, still more preferably 94 mol % or less, particularly preferably 92 mol % or less, and extremely preferably 90 mol % or less with respect to the total amount of all the monomers. By setting the content of the hydrophobic polymer to 98 mol % or less, solubility of the water-soluble polymer in water is sufficient.

The water-soluble polymer is a block copolymer having the hydrophobic block (A) and the anionic block (B). As a configuration of the blocks, an A-B type block copolymer, an A-B-A type block copolymer, or a B-A-B type block copolymer is preferable, and an A-B type block copolymer or an A-B-A type block copolymer is more preferable from a viewpoint of obtaining a polishing agent having a high selection ratio between the silicon oxide film and the stopper film.

Note that when two or more types of hydrophobic monomers are used, arrangement of the two or more types of hydrophobic monomers in the hydrophobic block is not particularly limited, and may be random or block.

When two or more types of anionic monomers are used, arrangement of the two or more types of anionic monomers in the anionic block is not particularly limited, and may be random or block.

A weight average molecular weight Mw of the water-soluble polymer is not particularly limited, but is preferably 2,000 to 50,000, more preferably 2,500 to 40,000, and still more preferably 3,000 to 30,000 from a viewpoint of dispersion stability.

The weight average molecular weight (Mw) is determined as a value in terms of standard polystyrene by gel permeation chromatography (GPC).

The water-soluble polymer may be a commercially available product or may be synthesized. As a synthesis method, for example, a block copolymer can be manufactured by first synthesizing an anionic block and polymerizing a hydrophobic monomer on the anionic block. In the above manufacturing method, the order of polymerization of the anionic block and the hydrophobic block may be reversed. The anionic block and the hydrophobic block may be separately synthesized, and then the anionic block and the hydrophobic block may be coupled.

The content of the water-soluble polymer is preferably 0.001 mass % to 1.0 mass %, more preferably 0.005 mass % to 0.8 mass %, still more preferably 0.01 mass % to 0.6 mass %, and particularly preferably 0.05 mass % to 0.2 mass % with respect to the total mass of the polishing agent from a viewpoint of a polishing suppressing effect of the stopper film.

### <Water>

The present polishing agent contains water as a medium for dispersing abrasive grains. The type of water is not particularly limited, but pure water, ultrapure water, deionized water, or the like is preferably used in consideration of an influence on other components, prevention of contamination with impurities, and an influence on pH or the like.

### <Additive>

The present polishing agent may further contain various additives. Examples of the additive include a pH adjuster, a dispersant, a water-soluble polymer, an aggregation inhibitor, a lubricant, a viscosity imparting agent, a viscosity modifier, and a preservative, and the present polishing agent may contain two or more types of additives.

### (pH Adjuster)

In order to adjust a pH to a predetermined value, the present polishing agent may contain a pH adjuster. The pH adjuster can be appropriately selected and used from an acidic compound, a basic compound, an amphoteric compound such as an amino acid, and salts thereof.

Examples of the acidic compound include an inorganic acid, an organic acid, or and salts thereof. Examples of the inorganic acid include nitric acid, sulfuric acid, hydrochloric acid, and phosphoric acid, and ammonium salts thereof, sodium salts thereof, potassium salts thereof, and the like may be used.

Examples of the organic acid include a compound having a carboxy group, a sulfo group, or a phospho group as an anionic group, an ammonium salt thereof, a sodium salt thereof, and a potassium salt thereof.

Examples of the organic acid having a carboxy group include: an alkyl monocarboxylic acid such as formic acid, acetic acid, or propionic acid;
a carboxylic acid having a heterocyclic ring, such as 2-pyridine carboxylic acid, 3-pyridine carboxylic acid, 4-pyridine carboxylic acid, 2,3-pyridine dicarboxylic acid, 2,4-pyridine dicarboxylic acid, 2,5-pyridine dicarboxylic acid, 2,6-pyridine dicarboxylic acid, 3,4-pyridine dicarboxylic acid, 3,5-pyridine dicarboxylic acid, pyrazine carboxylic acid, 2,3-pyrazine dicarboxylic acid, 2-quinoline carboxylic acid, pyroglutamic acid, picolinic acid, DL-pipecolic acid, 2-furancarboxylic acid, 3-furancarboxylic acid, tetrahydrofuran-2-carboxylic acid, or tetrahydrofuran-2,3,4,5-tetracarboxylic acid;
a carboxylic acid having an alicyclic ring, such as cyclopentanecarboxylic acid, cyclohexanecarboxylic acid, cycloheptanecarboxylic acid, or cyclohexylcarboxylic acid;
a carboxylic acid having an amino group, such as alanine, glycine, glycylglycine, aminobutyric acid, N-acetylglycine, N,N-di(2-hydroxyethyl) glycine, N-(tert-butoxycarbonyl) glycine, proline, trans-4-hydroxy-L-proline, phenylalanine, sarcosine, hydantoic acid, creatine, N-[tris(hydroxymethyl)methyl]glycine, glutamic acid, or aspartic acid;
a carboxylic acid having a hydroxy group, such as lactic acid, malic acid, citric acid, tartaric acid, glycolic acid, gluconic acid, salicylic acid, 2-hydroxyisobutyric acid, glyceric acid, 2,2-bis(hydroxymethyl) propionic acid, or 2,2-bis(hydroxymethyl) butyric acid;
a carboxylic acid (keto acid) having a ketone group, such as pyruvic acid, acetoacetic acid, or levulinic acid; and
a dicarboxylic acid such as oxalic acid, malonic acid, succinic acid, fumaric acid, maleic acid, glutaric acid, adipic acid, or phthalic acid.

When an acid is used as the pH adjuster in the present polishing agent, an inorganic acid is preferable, and in particular, nitric acid, sulfuric acid, hydrochloric acid, phosphoric acid, ammonium salts thereof, sodium salts thereof, and potassium salts thereof are preferable.

Examples of the basic compound include: ammonia, sodium hydroxide, potassium hydroxide, ammonium hydroxide, potassium carbonate, sodium carbonate, ammonium carbonate; a quaternary ammonium hydroxide such as tetramethylammonium hydroxide or tetraethylammonium hydroxide; and an amino alcohol such as monoethanolamine, diethanolamine, or triethanolamine.

Examples of the amphoteric compound include glycine, alanine, and phenylalanine.

The pH adjuster can be used singly or in combination of two or more types thereof. The present polishing agent has a pH of 2 to 13. A lower limit of the pH is preferably 2.5, more preferably 4, still more preferably 5, and particularly preferably 6. An upper limit of the pH is preferably 12, more preferably 11, still more preferably 10, particularly preferably 9, and extremely preferably 8.5. By adjusting the pH within the above range, aggregation of the abrasive grains can be suppressed, and the polishing speed of the insulating film and the selection ratio are excellent.

A content ratio of the pH adjuster only needs to be appropriately adjusted so as to be the pH described above. As an example, the content ratio of the pH adjuster can be 0.005 mass % to 2.0 mass %, and is preferably 0.01 mass % to 1.5 mass %, and more preferably 0.01 mass % to 0.3 mass % with respect to the total amount of the present polishing agent.

### (Dispersant)

The present polishing agent may contain a dispersant in order to improve dispersibility of the abrasive grains. Examples of the dispersant include an anionic surfactant, a cationic surfactant, a nonionic surfactant, and an amphoteric surfactant, and one or two or more of these can be used.

As the anionic surfactant, a polymer having a carboxy group, an ammonium carboxylate, or the like is preferable, and polyacrylic acid or a polyacrylate is preferable.

Examples of the cationic surfactant include a diallyldimethylammonium chloride polymer, a diallyldimethylammonium chloride/sulfur dioxide copolymer, a diallyldimethylammonium chloride/acrylamide copolymer, a diallyldimethylammonium chloride maleic acid copolymer, and a maleic acid/diallyldimethylammonium ethyl sulfate/sulfur dioxide copolymer.

A weight average molecular weight of the surfactant is preferably 10,000 to 100,000 from a viewpoint of polishing a polishing surface at a higher speed.

When a dispersant is used, the content thereof is preferably 0.0001 mass % to 0.3 mass %, more preferably 0.001 mass % to 0.2 mass %, and still more preferably 0.01 mass % to 0.15 mass % with respect to the total mass of the polishing agent from a viewpoint of polishing a polishing surface at a higher speed.

### (Lubricant)

The present polishing agent may contain a lubricant. The lubricant is used as necessary for improving lubricity of the polishing agent and improving in-plane uniformity of a polishing speed, and examples thereof include a water-soluble polymer such as polyethylene glycol or polyglycerin.

In the present polishing agent, when the above additives are used, the total content of the additives is preferably 0.01 mass % to 10.0 mass %, and more preferably 0.01 mass % to 5.0 mass % with respect to the total mass of the polishing agent from a viewpoint of obtaining a polishing agent having a high selection ratio between the silicon oxide film and the stopper film.

A method for preparing the present polishing agent only needs to be appropriately selected from among methods for uniformly dispersing or dissolving abrasive grains, a water-soluble polymer, and components used as necessary in water as a medium.

For example, it is preferable to prepare the present polishing agent by preparing each of a dispersion of abrasive grains and an aqueous solution of the water-soluble nitrogen-containing compound (also referred to as an additive solution for a polishing agent) and mixing these. According to this method, storage stability and transportation convenience of the dispersion and the additive solution for a polishing agent are excellent.

The present polishing agent is preferably prepared at the time of use by performing the above mixing in a polishing device.

### [Additive Solution for Polishing Agent]

An additive solution for a polishing agent of the present embodiment is an additive liquid for preparing a polishing agent by being mixed with a dispersion of abrasive grains as described above, and contains a water-soluble polymer and water, and may contain the components described as other components in the above polishing agent as necessary. Since these components are as described above, description thereof is omitted here.

Note that, when a polishing agent is prepared by mixing a dispersion of abrasive grains and an additive solution for a polishing agent which are two separate liquids, each of the concentration of the abrasive grains in the dispersion and the concentration of a water-soluble nitrogen-containing compound in the additive solution for a polishing agent is concentrated to 2 to 100 times the concentration at the time of using the polishing agent, and can be diluted to a predetermined concentration at the time of use. More specifically, for example, when each of the concentration of the abrasive grains in the dispersion and the concentration of the water-soluble nitrogen-containing compound in the additive solution for a polishing agent is concentrated to 10 times, 10 parts by mass of the dispersion, 10 parts by mass of the additive solution for a polishing agent, and 80 parts by mass of water are mixed and stirred to obtain a polishing agent.

By adding the additive solution for a polishing agent to the dispersion of abrasive grain, it is possible to obtain a polishing agent capable of suppressing the polishing speed of the stopper film to be low and achieving a high selection ratio and flatness while maintaining a high polishing speed of the silicon oxide film.

In the additive solution for a polishing agent, the content ratio (concentration) of the water-soluble polymer is preferably 0.001 to 30 mass %, more preferably 0.01 to 20 mass %, and still more preferably 0.1 to 10 mass % with respect to the amount of the entire additive solution.

In the dispersion of abrasive grains, the content ratio of abrasive grains is preferably 0.2 to 40 mass %, more preferably 1 to 20 mass %, and still more preferably 5 to 10 mass %.

### [Polishing Method]

A polishing method according to the present invention is a polishing method in which a polishing surface and a polishing pad are brought into contact with each other while a polishing agent is supplied, and polishing is performed by relative movement between the polishing surface and the polishing pad, and is a method in which a polishing surface containing silicon oxide of a semiconductor substrate is polished using the polishing agent according to the present invention as the polishing agent.

Here, examples of the polishing surface to be polished include a surface including a surface made of silicon dioxide of a semiconductor substrate, a blanket wafer in which a stopper film and a silicon oxide film are laminated on a surface of a semiconductor substrate, and a pattern wafer in which these film types are arranged in a pattern. Preferable examples of the semiconductor substrate include a substrate for STI. The polishing agent of the present invention is also effective for polishing for planarizing an interlayer insulating film between multilayer wiring lines in manufacture of a semiconductor device.

Examples of the silicon oxide film in the substrate for STI include a so-called PE-TEOS film formed by a plasma CVD method using tetraethoxysilane (TEOS) as a raw material. In addition, examples of the silicon oxide film include a so-called HDP film formed by a high-density plasma CVD method. In addition, a HARP film or an FCVD film formed by another CVD method, or an SOD film formed by spin coating can also be used. Examples of a silicon nitride film include a film formed by a low-pressure CVD method or a plasma CVD method using silane or dichlorosilane and ammonia as raw materials, and a film formed by an ALD method. In addition, examples of a polysilicon film include a polycrystalline grain-shaped film obtained by forming a film by a low-pressure CVD method or a plasma CVD method using silane as a raw material and then heat-treating the film.

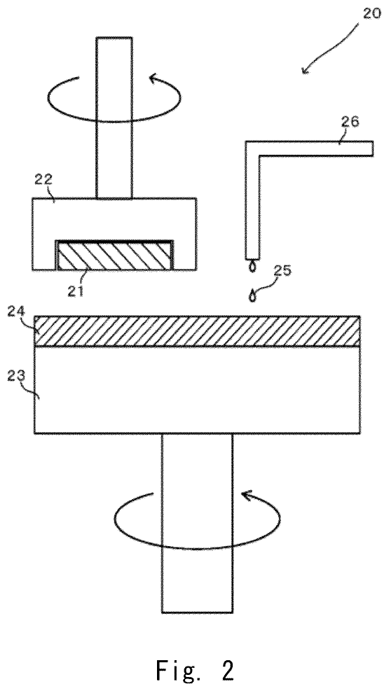

A known polishing device can be used for the present polishing method. FIG. 2 is a schematic view illustrating an example of a polishing device. A polishing device 20 illustrated in the example of FIG. 2 includes a polishing head 22 that holds a semiconductor substrate 21 such as an STI substrate, a polishing table 23, a polishing pad 24 attached to a surface of the polishing table 23, and a polishing agent supply pipe 26 that supplies a polishing agent 25 to the polishing pad 24. While the polishing agent 25 is supplied from the polishing agent supply pipe 26, a polishing surface of the semiconductor substrate 21 held by the polishing head 22 is brought into contact with the polishing pad 24, and the polishing head 22 and the polishing table 23 are relatively rotated to perform polishing.

The polishing head 22 may perform not only the rotational movement but also linear movement. In addition, each of the polishing table 23 and the polishing pad 24 may have a size equal to or smaller than the semiconductor substrate 21. In this case, it is preferable to be able to polish the entire polishing surface of the semiconductor substrate 21 by relatively moving the polishing head 22 and the polishing table 23. Furthermore, the polishing table 23 and the polishing pad 24 do not have to perform the rotational movement, and may move in one direction, for example, in a belt type form.

Polishing conditions of such a polishing device 20 are not particularly limited, but by applying a load to the polishing head 22 and pressing the polishing head 22 against the polishing pad 24, polishing pressure can be further increased, and the polishing speed can be improved. The polishing pressure is preferably about 0.5 to 50 kPa, and more preferably about 3 to 40 kPa from a viewpoint of uniformity and flatness in the polishing surface of the semiconductor substrate 21 at a polishing speed, and prevention of polishing defects such as scratches. Rotation speeds of the polishing table 23 and the polishing head 22 are preferably about 50 to 500 rpm. In addition, a supply amount of the polishing agent 25 is appropriately adjusted according to the composition of the polishing agent, the above-described polishing conditions, and the like.

As the polishing pad 24, one made of a nonwoven fabric, foamed polyurethane, a porous resin, a non-porous resin, or the like can be used. A surface of the polishing pad 24 may be grooved in a lattice shape, a concentric shape, a spiral shape, or the like in order to promote supply of the polishing agent 25 to the polishing pad 24 or to allow a certain amount of the polishing agent 25 to be accumulated in the polishing pad 24. In addition, if necessary, polishing may be performed while a surface of the polishing pad 24 is conditioned by bringing a pad conditioner into contact with the surface of the polishing pad 24.

According to the present polishing method, a high selection ratio between the silicon oxide film and the stopper film can be obtained while suppressing polishing scratches, and polishing with high flatness can be implemented.

### [Method for Manufacturing Semiconductor Component]

A method for manufacturing a semiconductor component according to the present embodiment is to obtain a semiconductor component by segmenting a semiconductor substrate having a polishing surface polished by the polishing method according to the present invention.

The method for manufacturing a semiconductor component according to the present disclosure includes a segmenting step of segmenting a semiconductor substrate having at least a polishing surface polished by the above polishing method. Examples of the segmenting step include a step of dicing the semiconductor substrate (for example, a semiconductor wafer) by a known method such as blade dicing, laser dicing, or plasma dicing to obtain a semiconductor component which is a semiconductor chip.

The present method for manufacturing a semiconductor component may further include a joining step of joining another member onto a polishing surface of the semiconductor chip. Through this step, a semiconductor component as a joint body is obtained.

Examples of the other member include a second semiconductor chip and a rewiring layer. Note that the second semiconductor chip may be a semiconductor chip obtained by the manufacturing method of the present disclosure, or may be a semiconductor chip obtained by another method. The joining step may be, for example, a step of directly disposing another member on the polishing surface and directly joining the polishing surface and the another member by fusion joining, surface activation joining, or the like, or may be a step of joining the polishing surface and another member via an adhesive layer. Examples of the adhesive layer include a metal layer such as solder or copper, a glass layer, and a resin layer such as polyimide or epoxy.

The present disclosure can further provide an electronic device including at least one semiconductor component having a polishing surface polished by the polishing method of the present disclosure.

### EXAMPLES

Hereinafter, the present invention will be specifically described with reference to Practical Examples and Comparative Examples, but the present invention is not limited to these Practical Examples. Examples 1 to 10 are Practical Examples, and Examples 11 and 19 are Comparative Examples.

### [Measurement Method]

<pH>

A pH was measured using a pH meter HM-30R manufactured by DKK-TOA CORPORATION at a temperature of 25±5° C.

### <Average Secondary Particle Size>

An average secondary particle size was measured using a laser scattering/diffraction type particle size distribution measuring device (manufactured by HORIBA, Ltd., device name: LA-950).

<Acid value>

An acid value was measured according to the method described in JIS K 0070:1992.

### <Weight Average Molecular Weight (Mw)>

A weight average molecular weight (Mw) was measured under the following conditions by gel permeation chromatography (GPC).
Device HLC-8320GPC (manufactured by Tosoh Corporation)
Column TSKgel GMPWXL (manufactured by Tosoh Corporation)
Detector RI detector polarity (+)
Eluent 0.2 M-NaNO₃ aqueous solution
Flow rate 1.0 mL/min column temperature 40° C.
Calculated by conversion using standard PEO/PEG

### [Polishing Agent]

### <Water-Soluble Polymer>

A water-soluble polymer having the following composition was prepared.

(Water-soluble polymer A) A water-soluble polymer A is a block copolymer containing, as hydrophobic monomers, n-butyl methacrylate, methyl methacrylate, and benzyl methacrylate in a molar ratio of 10:3:4 and containing methacrylic acid as an anionic monomer. The total amount of the hydrophobic monomers is 85 mol % with respect to the total amount of the monomers. An acid value is 100 mgKOH/g, and a weight average molecular weight is 9300.

(Water-soluble polymer B) A water-soluble polymer B is a block copolymer containing, as hydrophobic monomers, n-butyl methacrylate, methyl methacrylate, and benzyl methacrylate in a molar ratio of 10:3:4 and containing methacrylic acid as an anionic monomer. The total amount of the hydrophobic monomers is 82 mol % with respect to the total amount of the monomers. An acid value is 120 mgKOH/g, and a weight average molecular weight is 10600.

(Water-soluble polymer C) A water-soluble polymer C is a block copolymer containing n-butyl methacrylate as a hydrophobic monomer, containing acrylic acid as an anionic monomer, and containing vinylpyrrolidone as another monomer. The total amount of the hydrophobic monomer is 40 mol % with respect to the total amount of the monomers. An acid value is 80 to 120 mgKOH/g, and a weight average molecular weight is 9100.

(Water-soluble polymer D) A water-soluble polymer D is a block copolymer containing acrylic acid and acrylic acid amide and containing no hydrophobic monomer. An acid value is 80 to 120 mgKOH/g.

(Water-soluble polymer E) A water-soluble polymer E is a random copolymer containing methyl methacrylate as a hydrophobic monomer and containing acrylic acid as an anionic monomer. The total amount of the hydrophobic monomer is 91 mol % with respect to the total amount of the monomers. An acid value is 60 mgKOH/g.

(Water-soluble polymer F) A water-soluble polymer F is a random copolymer containing methyl methacrylate as a hydrophobic monomer and containing acrylic acid as an anionic monomer. The total amount of the hydrophobic monomer is 85 mol % with respect to the total amount of the monomers. An acid value is 100 mgKOH/g.

(Water-soluble polymer G) A water-soluble polymer G is a homopolymer of acrylic acid. A weight average molecular weight is 8000.

### <Preparation of Polishing Agent>

Abrasive grains, any one of the water-soluble polymers A to G, and water were mixed, and if necessary, a pH adjuster was further added thereto so as to have a desired pH to adjust each of polishing agents according to Examples 1 to 19 presented in Table 1. Note that, as the abrasive grains, ceria particles having an average secondary particle size of 200 nm were used, and the content thereof was 0.18 mass % with respect to the total mass of any one of the polishing agents. The content of ceria in one of the ceria particles was 95 mass % or more.

### [Polishing Evaluation]

### <Polishing Conditions>

Performance of each of the polishing agents according to Examples 1 to 19 was evaluated using a fully automatic CMP device FREX300X (manufactured by Ebara Corporation). In evaluation, a two-layer pad (IC-1570 manufactured by Rodel) was used as a polishing pad, and a diamond pad conditioner (manufactured by 3M, trade name: A165) was used for conditioning the polishing pad. As polishing conditions, polishing pressure was set to 21 kPa, a rotation speed of a polishing table was set to 100 rpm, and a rotation speed of a polishing head was set to 102 rpm. In addition, a supply speed of the polishing agent was 250 ml/min unless otherwise specified.

As a polishing target (object to be polished), the following objects were used.
A blanket wafer with a silicon dioxide film, in which a silicon dioxide film is formed on a 12 inch silicon substrate by plasma CVD using tetraethoxysilane as a raw material
A blanket wafer with a silicon nitride film, in which a silicon nitride film is formed on a 12 inch silicon substrate by low-pressure CVD using silane and ammonia as raw materials
A blanket wafer with a polysilicon film, obtained by forming a film on a 12 inch silicon substrate by low-pressure CVD using silane as a raw material and then heat-treating the film at 600° C.

### <Evaluation Method>

The film thicknesses of the silicon dioxide film, the silicon nitride film, and the polysilicon film formed were measured using a film thickness meter VM-3210 manufactured by SCREEN. By determining a difference between the film thickness of each blanket wafer before polishing and the film thickness thereof after polishing for one minute, a polishing speed of each of the silicon dioxide film, the silicon nitride film, and the polysilicon film was calculated. Calculation was performed by defining an average value (nm/min) of polishing speeds at 49 points in a plane of the substrate as a polishing speed, and defining a ratio between a polishing speed of the silicon dioxide film and a polishing speed of each stopper film (polishing speed of silicon dioxide film/polishing speed of silicon nitride film) as a selection ratio.

### <Evaluation Results>

Results obtained by measuring a polishing speed of each blanket wafer by the above method for each of the polishing agents according to Examples 1 to 19, and calculating a selection ratio are presented in Tables 1 and 2. Note that, in Tables, the silicon oxide film is denoted by “Ox”, the silicon nitride film is denoted by “SiN”, the polysilicon film is denoted by “pSi”, and the polishing speed is denoted by “RR”.

TABLE 1

| | | Example | Example | Example | Example | Example | Example |
|---|---|---|---|---|---|---|---|
| | | 1 | 2 | 3 | 4 | 5 | 6 |
| Water-soluble polymer | | A | A | A | A | A | B |
| | Content (mass %) | 0.04 | 0.04 | 0.04 | 0.15 | 0.50 | 0.04 |
| pH | | 6.4 | 7.5 | 8.0 | 7.0 | 7.0 | 6.4 |
| Evaluation | Ox RR (Å/min) | 838 | 1121 | 1096 | 923 | 685 | 1000 |
| results | SiN RR (Å/min) | 6 | 8 | 12 | 4 | 6 | 4 |
| | pSi RR (Å/min) | 6 | 7 | 10 | 3 | 7 | 4 |
| | Ox/SiN selection ratio | 137 | 142 | 93 | 242 | 120 | 259 |
| | Ox/pSi selection ratio | 131 | 172 | 115 | 317 | 101 | 230 |
| | | Example | Example | Example | Example | Example | Example |
| | | 7 | 8 | 9 | 10 | 11 | 12 |
| Water-soluble polymer | | B | B | B | B | C | C |
| | Content (mass %) | 0.04 | 0.04 | 0.15 | 0.50 | 0.04 | 0.04 |
| pH | | 7.3 | 7.8 | 6.4 | 6.3 | 4.9 | 6.8 |
| Evaluation | Ox RR (Å/min) | 1139 | 1057 | 766 | 755 | 792 | 784 |
| results | SiN RR (Å/min) | 6 | 5 | 5 | 5 | 39 | 26 |
| | pSi RR (Å/min) | 3 | 8 | 5 | 1 | 397 | 742 |
| | Ox/SiN selection ratio | 207 | 214 | 143 | 161 | 20.2 | 29.7 |
| | Ox/pSi selection ratio | 388 | 129 | 154 | 846 | 2.0 | 1.1 |

TABLE 2

| | | Example | Example | Example | Example | Example | Example | Example |
|---|---|---|---|---|---|---|---|---|
| | | 13 | 14 | 15 | 16 | 17 | 18 | 19 |
| Water-soluble polymer | | D | E | E | F | F | F | G |
| | Content (mass %) | 0.05 | 0.15 | 0.26 | 0.04 | 0.04 | 0.04 | 0.05 |
| pH | | 5.4 | 9.0 | 9.0 | 7.4 | 8.5 | 9.5 | 5.3 |
| Evaluation | Ox RR (Å/min) | 382 | 535 | 472 | 626 | 613 | 381 | 585 |
| results | SiN RR (Å/min) | 28 | 22 | 25 | 11 | 12 | 22 | 29 |
| | Ox/SiN selection ratio | 13.6 | 24.5 | 18.7 | 59.4 | 49.8 | 17.0 | 20.5 |

As in Examples 1 to 10, it is indicated that when the water-soluble polymer A or the water-soluble polymer B which is a block copolymer containing a hydrophobic monomer and an anionic monomer and containing the hydrophobic monomer in an amount of 50 mol % or more is used, the polishing speed of the silicon oxide film is high, the polishing speeds of the silicon nitride film and the polysilicon film are suppressed, and a high selection ratio is obtained.

On the other hand, as in Examples 11 and 12, it is indicated that when the water-soluble polymer C which is a block copolymer containing a hydrophobic monomer in an amount of less than 50 mol % is used, although the polishing speed of the silicon oxide film is high, the polishing speeds of the silicon nitride film and the polysilicon film are not sufficiently suppressed, and the selection ratio is decreased.

In addition, as in Example 13, it is indicated that when the water-soluble polymer D which is a block copolymer containing no hydrophobic monomer is used, the polishing speed of the silicon oxide film is low, the polishing speed of the silicon nitride film is not sufficiently suppressed, and the selection ratio is decreased.

In addition, as in Examples 14 to 18, it is indicated that when the water-soluble polymer E or the water-soluble polymer F which contains a hydrophobic monomer and an anionic monomer and contains the hydrophobic monomer in an amount of 50 mol % or more but is not a block copolymer but a random copolymer is used, the polishing speed of the silicon oxide film is low, the polishing speed of the silicon nitride film is not sufficiently suppressed, and the selection ratio is decreased.

In addition, as in Example 19, it is indicated that when the water-soluble polymer G which is a random copolymer containing no hydrophobic monomer is used, the polishing speed of the silicon oxide film is low, the polishing speed of the silicon nitride film is not sufficiently suppressed, and the selection ratio is decreased.

From the above, it is indicated that the polishing agent of the present invention which contains abrasive grains, a water-soluble polymer, and water, and in which the water-soluble polymer is a block copolymer containing a hydrophobic monomer and an anionic monomer, and the content of the hydrophobic monomer in the water-soluble polymer is 50 mol % or more has a high polishing speed of a silicon oxide film, and obtains a high selection ratio between an insulating film and a stopper film.

According to the present invention, high-speed polishing can be implemented, for example, in CMP of a polishing surface including an insulating film. Therefore, the polishing method of the present invention is suitable for polishing an insulating film for STI in manufacture of a semiconductor device.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing agent comprising abrasive grains, a water-soluble polymer, and water, wherein
the water-soluble polymer is a block copolymer containing a hydrophobic monomer and an anionic monomer, and
a content of the hydrophobic monomer in the water-soluble polymer is 50 mol % or more.

2. The polishing agent according to claim 1, wherein the abrasive grains contain at least one selected from the group consisting of silica particles, alumina particles, zirconia particles, cerium compound particles, titania particles, germania particles, and composite particles thereof.

3. The polishing agent according to claim 2, wherein the abrasive grains contain ceria particles.

4. The polishing agent according to claim 1, wherein a content of the abrasive grains is 0.01 mass % to 10.0 mass % with respect to a total mass of the polishing agent.

5. The polishing agent according to claim 1, wherein the hydrophobic monomer contains a compound selected from the group consisting of represented by the following formula (1), (meth)acrylamide, N,N-dimethyl (meth)acrylamide, N,N-diethyl (meth)acrylamide, N,N-dibutyl (meth)acrylamide, N-tert-butylacrylamide, N-phenyl (meth)acrylamide, and N-benzyl (meth)acrylamide: 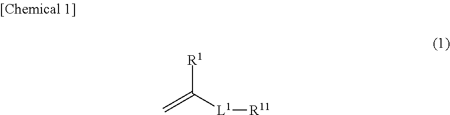
in which
R¹ is a hydrogen atom or a methyl group,
R¹¹ is a hydrocarbon group which may have O or Si between carbon-carbon atoms and in which a hydrogen atom may be replaced with a halogen atom, and
L¹ is a single bond or a divalent linking group.

6. The polishing agent according to claim 5, wherein the R¹¹ is a hydrocarbon group.

7. The polishing agent according to claim 1, wherein the anionic monomer contains a compound represented by the following formula (2): 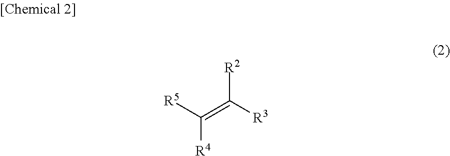
in which
R², R³, R⁴, and R⁵ are each independently a hydrogen atom, a hydrocarbon group, or a group having an anionic group or a salt thereof, at least one of R² to R⁵ is a group having an anionic group or a salt thereof, and when the compound has two or more carboxy groups in a molecule thereof, the carboxy groups may form an anhydride.

8. The polishing agent according to claim 7, wherein the anionic group contains a carboxy group, a sulfo group, a phosphonic acid, a phosphate, or a phenolic hydroxy group.

9. The polishing agent according to claim 7, wherein the anionic group contains a carboxy group.

10. The polishing agent according to claim 1, wherein the water-soluble polymer has a weight average molecular weight of 2,000 to 50,000.

11. The polishing agent according to claim 1, wherein a content of the water-soluble polymer is 0.02 mass % to 0.5 mass % with respect to a total mass of the polishing agent.

12. The polishing agent according to claim 1, having a pH of 4 to 13.

13. A polishing method for bringing a polishing surface of a semiconductor substrate and a polishing pad into contact with each other while supplying a polishing agent, and performing polishing by relative movement between the polishing surface and the polishing pad,
wherein the polishing agent is the polishing agent according to claim 1.

14. A method for manufacturing a semiconductor component, the method comprising segmenting a semiconductor substrate having a polishing surface polished by the polishing method according to claim 13 to obtain a semiconductor component.

15. An additive solution for a polishing agent comprising a water-soluble polymer and water, wherein
the water-soluble polymer is a block copolymer containing a hydrophobic monomer and an anionic monomer, and
a content of the hydrophobic monomer in the water-soluble polymer is 50 mol % or more.
